(19) United States
(12) Patent Application Publication
(10) Pub. No.: US 2026/0082686 A1
(43) Pub. Date: Mar. 19, 2026

(54) SEMICONDUCTOR DEVICE

(71) Applicant: Murata Manufacturing Co., Ltd., Nagaokakyo-shi (JP)

(72) Inventor: Masatomi HARADA, Nagaokakyo-shi (JP)

(21) Appl. No.: 19/400,643

(22) Filed: Nov. 25, 2025

Related U.S. Application Data
(63) Continuation of application No. PCT/JP2024/017949, filed on May 15, 2024.

(30) Foreign Application Priority Data
Jun. 7, 2023 (JP) 2023-094199

(51) Int. Cl. H10D 84/00

(52) U.S. Cl. CPC H10D 84/212

(57) ABSTRACT

A semiconductor device is provided that includes a substrate; N first electrodes over the substrate; a first dielectric film on the N first electrodes; M second electrodes over the N first electrodes with the first dielectric film interposed therebetween; a first protective layer covering the N first electrodes and the M second electrodes; three or more outer electrodes that extend through the first protective layer; and a second protective layer that covers each outer electrode of the three or more outer electrodes, other than two outer electrodes. At least one of the second electrodes is located over each first electrode, and the N first electrodes, the first dielectric film, and the M second electrodes form M capacitor elements that are electrically coupled in series.

### CROSS REFERENCE TO RELATED APPLICATIONS

This application is a continuation of PCT Application No. PCT/JP2024/017949, filed May 15, 2024, which claims priority to Japanese Patent Application No. 2023-094199, filed Jun. 7, 2023, the entire contents of each of which are hereby incorporated by reference in their entireties.

### TECHNICAL FIELD

The present invention relates to semiconductor devices.

### BACKGROUND

Currently, a metal-insulator-metal (MIM) capacitor can be used as a typical capacitor element in a semiconductor integrated circuit. An MIM capacitor has a parallel-plate structure including an insulator and lower and upper electrodes on both sides of the insulator.

Japanese Unexamined Patent Application Publication No. 2017-112525 discloses a branching filter including a common port; a first signal port; a second signal port; a low pass filter provided between the common port and the first signal port, and configured to selectively pass a signal of a frequency within a first passband not higher than a first cut-off frequency; and a high pass filter provided between the common port and the second signal port, and configured to selectively pass a signal of a frequency within a second passband not lower than a second cut-off frequency higher than the first cut-off frequency, in which the low pass filter includes: a first LC resonant circuit; and a first acoustic wave resonator provided in a shunt circuit connecting a path leading from the first LC resonant circuit to the first signal port to a ground, and the first acoustic wave resonator has a resonant frequency higher than the first cut-off frequency.

Moreover, Japanese Patent No. 6372677 discloses a method of manufacturing a capacitor that includes a step of forming a dielectric film on a wafer; a step of forming, in a monitoring region included in a portion of a region in which the dielectric film is formed on the wafer, a monitoring electrode, a wafer-facing surface of which has a predetermined area; a step of measuring a capacitance value of the capacitance formed by the dielectric film and the monitoring electrode formed in the monitoring region; a step of calculating, on the basis of the measured capacitance value, an area of an upper electrode formed in a capacitor-forming region which is a region other than the monitoring region in the portion of the region; and a step of forming, on the basis of the calculated area, the upper electrode in the capacitor-forming region.

In general, a high frequency circuit in a communication RF module uses high frequency of 700 MHz or more. To increase communication speed, high frequency of 3 GHz or more will be used in the future.

FIG. 19 is a circuit diagram of a filter circuit according to a comparative configuration.

For example, a filter circuit that does not transmit a desired frequency to subsequent circuits can be achieved as in FIG. 1 of Japanese Unexamined Patent Application Publication No. 2017-112525 or as shown in FIG. 19. In particular, an inductor L and a capacitor C are coupled in series, so that signals at the resonant frequency f0=½π√(LC) flow to the ground.

The higher the frequency, the larger the influence that variations in constants such as L and C have on the resonant frequency. Hence, for high-frequency circuits, components with the tightest deviation in their specifications are selected.

As an example, in the LC filter circuit of FIG. 19, when L=1 nH and C=1 pF, f0 is 5.03 GHZ. Then, if C has a capacitance deviation of +0.05 pF, that is, if C varies from 0.95 pF to 1.05 pF, f0 varies from 4.91 GHz to 5.16 GHz. As a filter characteristic of a high frequency circuit, the variation in the resonant frequency f0 mentioned above can be critical in some cases.

To solve the problem mentioned above, selecting components having tighter deviations for C and L is a conceivable way. However, conventional electronic components have limitations on the minimum values of their deviations, and hence such an approach is sometimes impractical.

### SUMMARY OF THE INVENTION

In view of the foregoing, it is an object of the present disclosure to provide a semiconductor device having a small capacitance deviation.

In an exemplary aspect, a semiconductor device is provided that includes a substrate; N first electrodes over the substrate, where N is an integer of 2 or more; a first dielectric film on the N first electrodes; M second electrodes over the N first electrodes with the first dielectric film interposed therebetween, where M is an integer of 3 or more and M>N; a first protective layer that covers the N first electrodes and the M second electrodes; three or more outer electrodes that extend through the first protective layer; and a second protective layer that covers each outer electrode of the three or more outer electrodes, other than two outer electrodes. In this aspect, at least one of the second electrodes is located over each first electrode. Moreover, the N first electrodes, the first dielectric film, and the M second electrodes form M capacitor elements that are electrically coupled in series. Each pair of capacitor elements of the M capacitor elements, including two of the second electrodes located over the same first electrode, are electrically coupled in series by the same first electrode. The two outer electrodes not covered by the second protective layer are configured as terminal electrodes that are respectively electrically coupled to two capacitor elements of the M capacitor elements. Each pair of capacitor elements of the M capacitor elements, including two of the second electrodes located over different ones of the first electrodes, are electrically coupled in series by one of the outer electrodes, not serving as the two terminal electrodes, and each outer electrode not serving as the two terminal electrodes is covered with the second protective layer.

With the exemplary aspects of the present disclosure, a semiconductor device is provided that has a small capacitance deviation.

### BRIEF DESCRIPTION OF DRAWINGS

FIG. 1 is a schematic cross-sectional view of an example of a capacitor according to a first exemplary embodiment.

FIG. 2 is a schematic plan view of the example of the capacitor according to the first exemplary embodiment.

FIG. 3 illustrates an equivalent circuit of the capacitor illustrated in FIGS. 1 and 2.

FIG. 4 is a schematic cross-sectional view of an example of a capacitor according to a second exemplary embodiment.

FIG. 5 is a schematic plan view of the example of the capacitor according to the second exemplary embodiment.

FIG. 6 illustrates an equivalent circuit of the capacitor illustrated in FIGS. 4 and 5.

FIG. 7 is a schematic cross-sectional view of an example of a capacitor according to a third exemplary embodiment.

FIG. 8 is a schematic plan view of the example of the capacitor according to the third exemplary embodiment.

FIG. 9 illustrates an equivalent circuit of the capacitor illustrated in FIGS. 7 and 8.

FIG. 10 is a schematic cross-sectional view of an example of a capacitor according to a fourth exemplary embodiment.

FIG. 11 is a schematic plan view of the example of the capacitor according to the fourth exemplary embodiment.

FIG. 12 illustrates an equivalent circuit of the capacitor illustrated in FIGS. 10 and 11.

FIG. 13 is a schematic cross-sectional view of an example of a capacitor according to a fifth exemplary embodiment.

FIG. 14 is a schematic plan view of the example of the capacitor according to the fifth exemplary embodiment.

FIG. 15 illustrates an equivalent circuit of the capacitor illustrated in FIGS. 13 and 14.

FIG. 16 is a schematic cross-sectional view of an example of a capacitor according to a sixth exemplary embodiment.

FIG. 17 is a schematic plan view of the example of the capacitor according to the sixth exemplary embodiment.

FIG. 18 illustrates an equivalent circuit of the capacitor illustrated in FIGS. 16 and 17.

FIG. 19 is a circuit diagram of a filter circuit according to a comparative configuration.

### DETAILED DESCRIPTION OF EMBODIMENTS

Hereinafter, semiconductor devices according to exemplary aspects of the present disclosure will be described.

However, it is noted that the present disclosure is not limited to the following configurations, which may be changed and applied as appropriate within the scope not departing from the spirit of the exemplary aspects of the present disclosure. Combinations of two or more individual preferred configurations according to the present disclosure described in the following are also included as would be appreciated to one skilled in the art.

Each exemplary embodiment in the following disclosure is provided as an example. Hence, it goes without saying that configurations shown in different embodiments can be partially replaced or combined with one another as would be appreciated to one skilled in the art. Moreover, for a second and subsequent embodiments, description of the items common to those of a first embodiment will be omitted, and only different points will be described. In particular, the same or similar operational advantages by the same or similar configurations will not be referred to in each embodiment.

In the following description, when each embodiment is not particularly distinguished, the term “semiconductor device of the present disclosure” is simply used. The shapes, arrangement, and other conditions of the semiconductor device of the present disclosure and its components are not limited to the illustrated examples.

The following description is based on an example of a capacitor, which is an exemplary embodiment of a semiconductor device of the present disclosure. It is noted that a semiconductor device of the present disclosure may refer to a capacitor alone, or to a device including a capacitor.

In an exemplary aspect, a semiconductor device of the present disclosure includes a substrate; N first electrodes over the substrate, where N is an integer of 2 or more; a first dielectric film on the N first electrodes; M second electrodes over the N first electrodes with the first dielectric film interposed therebetween, where M is an integer of 3 or more and M>N; a first protective layer that covers the N first electrodes and the M second electrodes; three or more outer electrodes that extend through the first protective layer; and a second protective layer that covers each outer electrode of the three or more outer electrodes, other than two outer electrodes. At least one of the second electrodes is located over each first electrode. The N first electrodes, the first dielectric film, and the M second electrodes form M capacitor elements that are electrically coupled in series. Each pair of capacitor elements of the M capacitor elements, including two of the second electrodes located over the same first electrode, are electrically coupled in series by the same first electrode. The two outer electrodes not covered by the second protective layer are configured as terminal electrodes respectively electrically coupled to two capacitor elements of the M capacitor elements. Each pair of capacitor elements of the M capacitor elements, including two of the second electrodes located over different ones of the first electrodes, are electrically coupled in series by one of the outer electrodes, not serving as the two terminal electrodes. Finally, each outer electrode not serving as the two terminal electrodes is covered with the second protective layer.

In the present specification, the terms “first, second, third, fourth, and so on” respectively refer to the electrodes located at the first layer (e.g., a first position), second layer (e.g., a second position), third layer (e.g., a third position), fourth layer (e.g., a fourth position), and subsequent layers (e.g., subsequent positions) counted from the substrate side among the electrodes forming capacitor elements.

In the present specification, “a capacitor element” refers an element (e.g., a sub-capacitor) composed of a dielectric film and a pair of electrodes facing each other with the dielectric film interposed therebetween, and “a capacitor” indicates a concept including a plurality of capacitor elements.

### First Exemplary Embodiment

A capacitor according to the first exemplary embodiment includes two (that is, N=2) first electrodes, three (that is, M=3) second electrodes, and three outer electrodes.

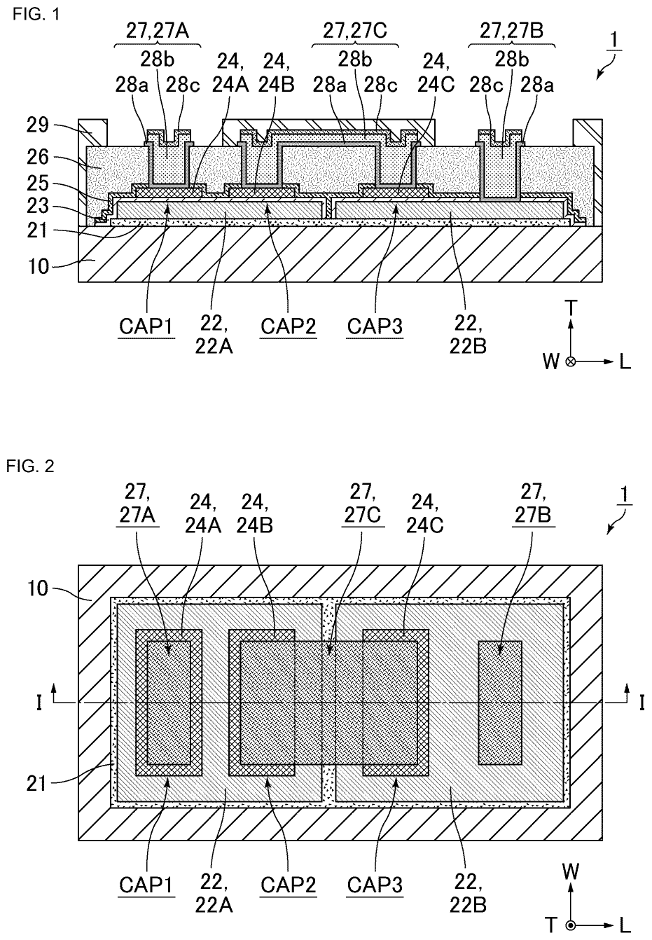

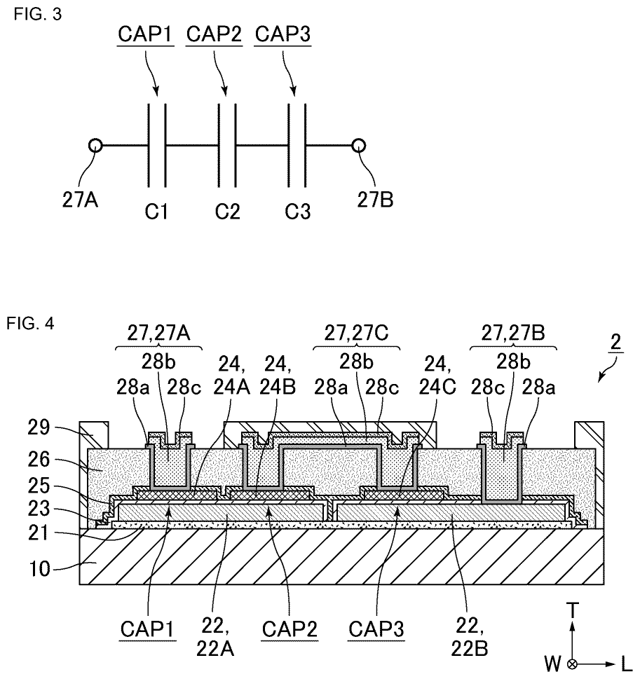

FIG. 1 is a schematic cross-sectional view of an example of a capacitor according to the first exemplary embodiment. FIG. 2 is a schematic plan view of the example of the capacitor according to the first exemplary embodiment. FIG. 1 is a cross-sectional view of the capacitor illustrated in FIG. 2, taken along line I-I. FIG. 3 illustrates an equivalent circuit of the capacitor illustrated in FIGS. 1 and 2.

In the present specification, the longitudinal direction, the width direction, and the thickness direction of a capacitor (e.g., the semiconductor device) are defined as the directions determined by arrow L, arrow W, and arrow T as shown in FIGS. 1 and 2 and other figures. Note that the longitudinal direction L, the width direction W, and the thickness direction T are orthogonal to one another.

The capacitor 1 illustrated in FIGS. 1 and 2 includes a substrate 10; an insulating film 21 provided on the substrate 10; two first electrodes 22 provided on the insulating film 21; a first dielectric film 23 provided on the two first electrodes; three second electrodes 24 provided over the two first electrodes 22 with the first dielectric film 23 interposed therebetween; a moisture resistance film 25 provided on the first dielectric film 23 and the second electrodes 24; a first protective layer 26 covering the two first electrodes 22, the three second electrodes 24, and the moisture resistance film 25; three outer electrodes 27 passing through the first protective layer 26; and a second protective layer 29 covering one outer electrode 27 of the three outer electrodes 27, other than two outer electrodes 27.

When one of the two first electrodes 22 is referred to as a first electrode 22A, and the other as a first electrode 22B, the second electrodes 24 include second electrodes 24A and 24B provided over the first electrode 22A and a second electrode 24C provided over the first electrode 22B.

Then, at least one of the second electrodes 24 is located over each first electrode 22; the two first electrodes 22, the first dielectric film 23, and the three second electrodes 24 form three capacitor elements CAP1, CAP2, and CAP3; the three capacitor elements CAP1, CAP2, and CAP3 are electrically coupled in series (see FIG. 3); the two capacitor elements CAP1 and CAP2 of the three capacitor elements CAP1, CAP2, and CAP3, including the two second electrodes 24A and 24B located over the same first electrode 22A, are electrically coupled in series by the same first electrode 22A; the two outer electrodes 27 not covered by the second protective layer 29 serve as two terminal electrodes 27A and 27B respectively electrically coupled to the two capacitor elements CAP1 and CAP3 of the three capacitor elements CAP1, CAP2, and CAP3; the two capacitor elements CAP2 and CAP3 of the three capacitor elements CAP1, CAP2, and CAP3, including the two second electrodes 24B and 24C located over the different first electrodes 22A and 22B, are electrically coupled in series by the outer electrode 27C not serving as the two terminal electrodes 27A and 27B; and the outer electrode 27C not serving as the two terminal electrodes 27A and 27B is covered with the second protective layer 29.

According to the exemplary aspect, this configuration forms a capacitor having a small capacitance deviation (e.g., a capacitance variation). The reason is as follows.

Assume that a generated capacitance is C0±ΔC0 due to variation in the film thickness of the dielectric film on the wafer surface. The capacitance generated by the configuration including the three series capacitor elements described above is calculated from 1/C=1/C1+1/C2+1/C3, where C1, C2, and C3 are the capacitances of the capacitor elements CAP1, CAP2, and CAP3, and the result is C0/3+ΔC0/3. Thus, the series coupling of three capacitors reduces the capacitance deviation to one-third.

The target capacitance C0/3 can be achieved whether the capacitances C1, C2, and C3 have the same value or a combination of different values. However, the capacitance variation including the film thickness variation of the dielectric film is different depending on the capacitances; and in the case in which C1, C2, and C3 are different capacitances, the total capacitance variation ΔC0/3 is larger. Hence, it is preferable that the capacitances C1, C2, and C3 are the same.

In the present specification, the expression that certain values are the same also encompasses cases in which the values are substantially the same.

As another benefit, coupling a plurality of capacitor elements in series makes it easy to form a capacitor having low capacitance. For example, in the case in which a dielectric film having a film thickness of 1 μm is used to form one capacitor in one chip, its capacitance is 1 pF. In the above-mentioned configuration, since the area of the electrodes is reduced to one-fourth, and three capacitors elements are coupled in series, a capacitor can be formed having a low capacitance of 0.1 pF or less.

In addition, since the two capacitor elements CAP2 and CAP3 formed by the different first electrodes 22A and 22B are electrically coupled in series not by a common second electrode, but by the outer electrode 27C passing through the first protective layer 26, the interference can be reduced between the capacitor elements CAP2 and CAP3. In particular, in the case in which the substrate 10 is a semiconductor substrate, this interference can be reduced.

Hereinafter, each configuration will be described in detail.

Although the material of the substrate 10 is not particularly limited, it is preferably a semiconductor substrate, such as a silicon substrate or a gallium arsenide substrate, or an insulating substrate formed of a material such as glass or alumina.

In the exemplary aspect, the insulating film 21 is provided to cover the entire part of one main surface of the substrate 10. Although the insulating film 21 may be provided to cover part of one main surface of the substrate 10, it needs to be provided in a region larger than the first electrodes 22 and overlapping the entire parts of the first electrodes 22. In the case in which the substrate 10 is an insulating substrate formed of a material such as glass and alumina, the insulating film 21 is not necessary.

Specifically, providing the insulating film 21 electrically insulates the capacitor elements CAP1, CAP2, and CAP3 from the semiconductor substrate. This configuration reduces the parasitic capacitance components of the capacitor elements CAP1, CAP2, and CAP3.

It is noted that the material of the insulating film 21 is not particularly limited, and preferable examples for the material include SiO₂, SiN, Al₂O₃, HfO₂, Ta₂O₅, and ZrO₂.

The first electrodes 22 are provided at positions away from the end portions of the substrate 10. Specifically, the end portions of the first electrodes 22 are positioned on the inner sides of the end portions of the substrate 10.

It is noted that the material of the first electrodes 22 is not particularly limited, and preferred examples of the material include Cu, Ag, Au, Al, Ni, Cr, Ti, and an alloy containing at least one of these metals.

The first dielectric film 23 is provided to cover the first electrodes 22 except for an opening. In FIG. 1, the end portions of the first dielectric film 23 are also provided on the surface of the insulating film 21 from the end portions of the first electrodes 22 to the end portions of the substrate 10. However, the end portions of the first dielectric film 23 need not necessarily be provided to extend to the end portions of the substrate 10.

Moreover, it is noted that the material of the first dielectric film 23 is not particularly limited, and preferred examples of the material include oxides or nitrides such as SiO₂, SiN, Al₂O₃, HfO₂, and Ta₂O₅.

The second electrodes 24 are provided to face the first electrodes 22 with the first dielectric film 23 interposed therebetween. More specifically, the second electrodes 24A and 24B face the first electrode 22A, and the second electrode 24C faces the first electrode 22B.

In the present embodiment, as illustrated in FIG. 2, the areas of the three second electrodes 24 are the same, and the plan-view shapes of the three second electrodes 24 are also the same. Specifically, the three second electrodes 24 have the same rectangular shape having the same dimensions in the longitudinal direction L and the width direction W.

In the present specification, the term “the area” refers to the area in a plan view in the thickness direction T, and the term “plan-view shape” refers to the shape in a plan view in the thickness direction T.

It is noted that the material of the second electrodes 24 is not particularly limited, and preferred examples of the material include Cu, Ag, Au, Al, Ni, Cr, Ti, and an alloy containing at least one of these metals.

The moisture resistance film 25 is provided to cover the first dielectric film 23 and the second electrodes 24 except for the opening. Providing the moisture resistance film 25 increases the moisture resistance of the capacitor elements, in particular, the moisture resistance of the first dielectric film 23. However, the moisture resistance film 25 is not essential.

It is noted that the material of the moisture resistance film 25 is not particularly limited, and preferred examples of the material include moisture-resistant materials such as SiO₂ and SiN.

The first protective layer 26 has openings at the position overlapping the opening of the first dielectric film 23 and the moisture resistance film 25 (e.g., the opening overlapping the first electrode 22B) and at the positions overlapping the openings of the moisture resistance film 25 (e.g., the openings overlapping the second electrodes 24). Providing the first protective layer 26 protects the capacitor elements, in particular, the first dielectric film 23 against moisture.

It is noted that the material of the first protective layer 26 is not particularly limited, and preferred examples include resin materials such as a polyimide resin and a resin used in a solder resist.

The film thickness of the first protective layer 26 is not particularly limited and is preferably 0.5 μm or more and 10 μm or less, more preferably 1 μm or more and 5 μm or less. The outer electrode 27C formed over the first protective layer 26 having such a film thickness electrically couples the two capacitor elements CAP2 and CAP3, thereby reducing the electric field coupling between the first electrodes 22 and the outer electrode 27C. This configuration reduces the parasitic capacitance components of the capacitor elements CAP1, CAP2, and CAP3, and employment of this configuration and the insulating film 21 minimizes the parasitic capacitance components of the capacitor elements CAP1, CAP2, and CAP3.

The outer electrodes 27 serving as (e.g., configured as) the terminal electrodes 27A and 27B are respectively electrically coupled to the capacitor elements (in this case, the capacitor element CAP1 and CAP3) coupled in series at both ends among the three capacitor elements CAP1, CAP2, and CAP3. More specifically, the outer electrodes 27 configured as the terminal electrodes 27A and 27B are coupled to the second electrode 24A and the first electrode 22B, respectively.

The outer electrode 27C not configured as the terminal electrodes 27A and 27B is a connection wiring line and is electrically coupled to the capacitor element (in this case, the capacitor element CAP2) other than the capacitor elements coupled in series at both ends and another capacitor element (in this case, the capacitor element CAP3), among the three capacitor elements CAP1, CAP2, and CAP3. More specifically, the outer electrode 27C is coupled to the second electrodes 24B and 24C.

It is noted that the material of the outer electrodes 27 is not particularly limited, and preferred examples of the material include Cu, Ni, Ag, Au, and Al. The outer electrodes 27 may have a single-layer structure or a multilayer structure. The outermost surfaces of the outer electrodes 27 are preferably composed of Au or Sn.

In the case in which the outer electrodes 27 have a multilayer structure, each outer electrode 27 may include a seed layer 28a, a first plating layer 28b, and a second plating layer 28c in this order from the substrate 10 side as illustrated in FIG. 1.

Examples of the seed layers 28a of the outer electrodes 27 include a multilayer material (Ti/Cu) including a conductor layer composed of titanium (Ti) and a conductor layer composed of copper (Cu).

Examples of the constituent material of the first plating layers 28b of the outer electrodes 27 include nickel (Ni).

Examples of the constituent material of the second plating layers 28c of the outer electrodes 27 include gold (Au) and tin (Sn).

It is noted that the materials of the three the outer electrodes 27 may be the same or different.

The second protective layer 29 has openings through which the terminal electrodes 27A and 27B are exposed. The second protective layer 29 insulates the outer electrode 27 (the outer electrode 27C) other than the terminal electrodes 27A and 27B from the outside. Providing the second protective layer 29 protects the capacitor elements, in particular, the first dielectric film 23 more effectively against moisture.

It is noted that the material of the second protective layer 29 is not particularly limited, and preferred examples include resin materials such as a polyimide resin and a resin used in a solder resist.

It is noted that the distance between adjacent capacitor elements is not particularly limited and is preferably 5 μm or more and 100 μm or less, more preferably 10 μm or more and 50 μm or less. The distance of 100 μm or less reduces the difference in the film thickness of the first dielectric film 23 between the capacitor elements and makes it possible to form capacitor elements having the same capacitance.

The capacitor 1 illustrated in FIGS. 1 and 2 is manufactured, for example, by using a method the same as or similar to a method of manufacturing general MIM capacitors as would be appreciated to one skilled in the art.

### Second Exemplary Embodiment

A capacitor according to the second exemplary embodiment of the present disclosure is different from the capacitor of the first exemplary embodiment in that the areas of at least two of the three second electrodes are different from each other.

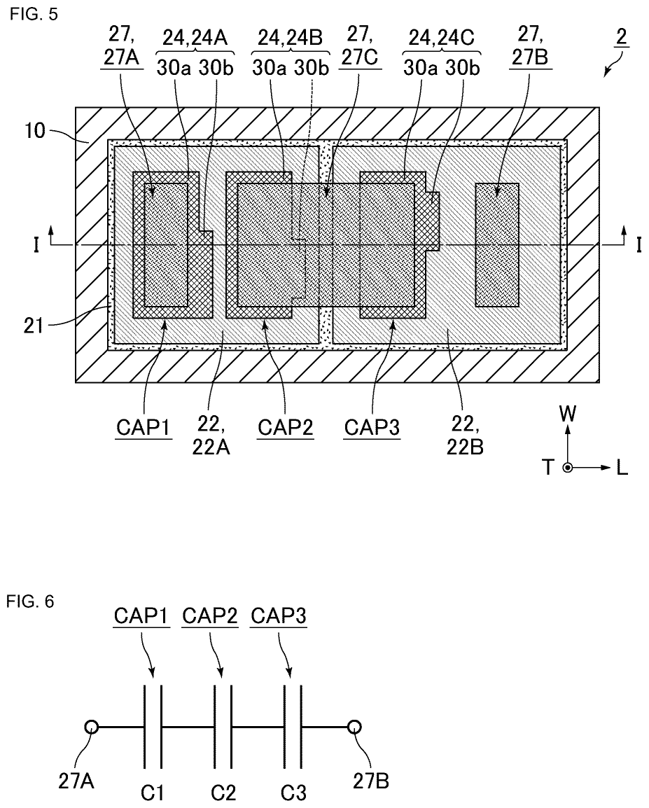

FIG. 4 is a schematic cross-sectional view of an example of a capacitor according to the second exemplary embodiment. FIG. 5 is a schematic plan view of the example of the capacitor according to the second exemplary embodiment. FIG. 4 is a cross-sectional view of the capacitor illustrated in FIG. 5, taken along line I-I. FIG. 6 illustrates an equivalent circuit of the capacitor illustrated in FIGS. 4 and 5.

Although the capacitance variation can be reduced in the capacitor 1 illustrated in FIGS. 1 and 2, there is a possibility that the capacitance center is deviated from a desired value.

Unlike the capacitor 1, in the capacitor 2 illustrated in FIGS. 4 and 5, the areas of at least two of the three second electrodes 24 are different from each other. This configuration makes it possible to adjust the capacitance center. This is because the area of each second electrode 24 can be set such that the film thickness distribution of the first dielectric film 23 on the wafer surface is canceled.

More specifically, each second electrode 24 includes a first region 30a having a rectangular plan-view shape and a second region 30b having a rectangular plan-view shape protruding from the first region 30a. Then, whereas the areas of the first regions 30a of the three second electrodes 24 are the same, the areas of the second regions 30b of at least two of the three second electrodes 24 are different from each other.

The areas of all of the second electrodes 24 may be different from one another, and the areas of the second regions 30b of all of the second electrodes 24 may be different from one another.

The capacitor 2 illustrated in FIGS. 4 and 5 is manufactured, for example, by using the method described in Japanese Patent No. 6372677 noted above.

The present embodiment makes it possible to adjust the capacitance center to a desired value. In addition, since the areas of the second electrodes 24 can be corrected such that the film thickness distribution of the first dielectric film 23 on the wafer surface is canceled, the capacitance distribution can be reduced. In summary, the exemplary configuration provides a capacitor in which the capacitance center is adjusted and the capacitance variation is reduced.

### Third Exemplary Embodiment

A capacitor according to the third exemplary embodiment of the present disclosure is different from the capacitor of the second exemplary embodiment in that the former further includes a second dielectric film and three (that is, M=3) third electrodes over the three (that is, M=3) second electrodes, and in that the areas of at least two of the three third electrodes are different from each other.

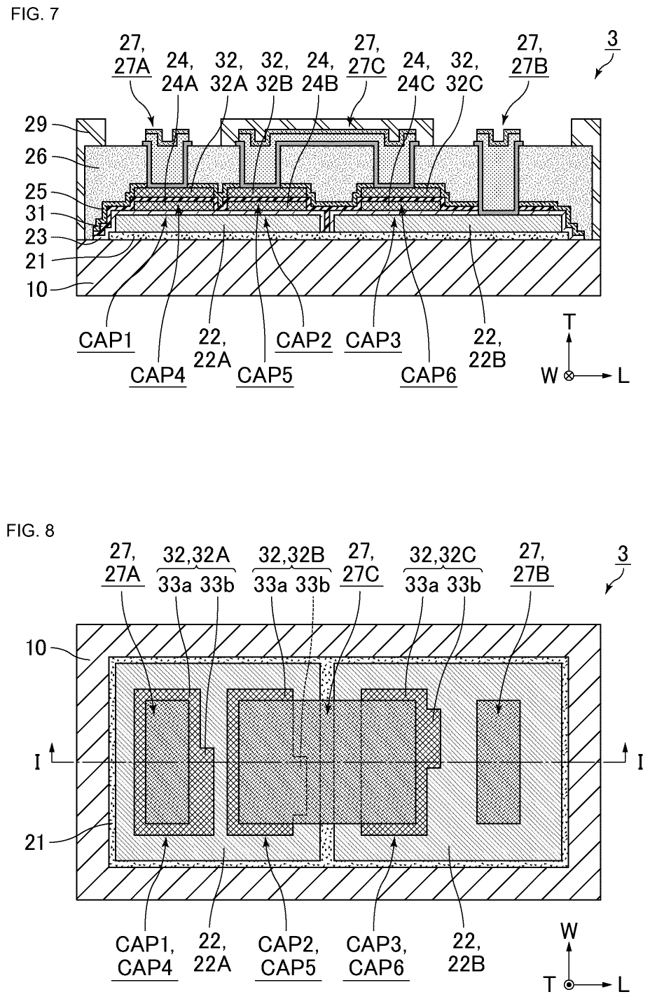

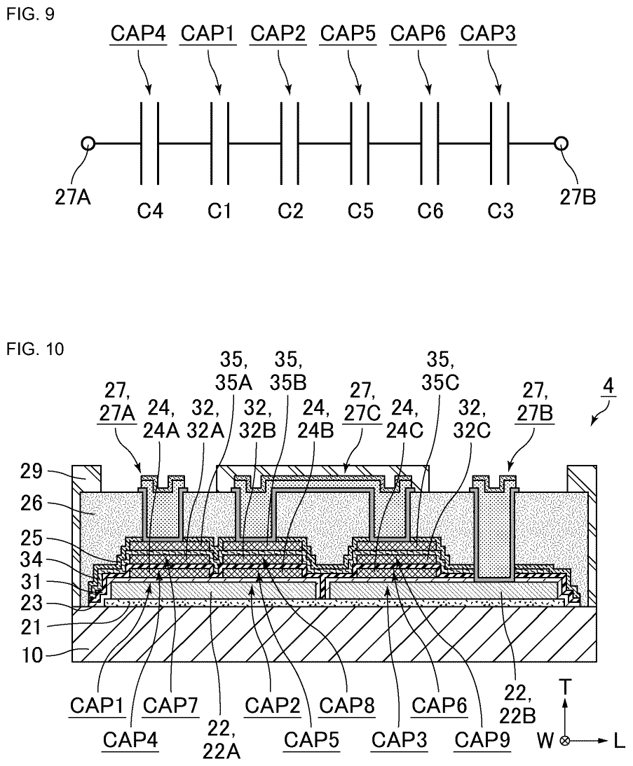

FIG. 7 is a schematic cross-sectional view of an example of a capacitor according to the third exemplary embodiment. FIG. 8 is a schematic plan view of the example of the capacitor according to the third exemplary embodiment. FIG. 7 is a cross-sectional view of the capacitor illustrated in FIG. 8, taken along line I-I. FIG. 9 illustrates an equivalent circuit of the capacitor illustrated in FIGS. 7 and 8.

The capacitor 3 illustrated in FIGS. 7 and 8 further includes a second dielectric film 31 provided on the three second electrodes 24, and three third electrodes 32 each provided over the corresponding one of the three second electrodes 24 with the second dielectric film 31 interposed therebetween.

Specifically, the three second electrodes 24, the second dielectric film 31, and the three third electrodes 32 form three capacitor elements CAP4, CAP5, and CAP6, and the six capacitor elements CAP1 to CAP6 are electrically coupled in series (see FIG. 9).

Thus, the present embodiment has a greater number of capacitor elements coupled in series, thereby further reducing the capacitance variation. In addition, since the capacitor elements are formed in the thickness direction, the chip can be downsized.

In the capacitor 3 illustrated in FIGS. 7 and 8, the areas of at least two of the three third electrodes 32 are different from each other. This configuration makes it possible to adjust the capacitance center. This is because the area of each third electrode 32 can be set such that the film thickness distribution of the second dielectric film 31 on the wafer surface is canceled.

More specifically, each third electrode 32 includes a first region 33a having a rectangular plan-view shape and a second region 33b having a rectangular plan-view shape protruding from the first region 33a. Then, whereas the areas of the first regions 33a of the three third electrodes 32 are the same, the areas of the second regions 33b of at least two of the three third electrodes 32 are different from each other.

The areas of all of the third electrodes 32 may be different from one another, and the areas of the second regions 33b of all of the third electrodes 32 may be different from one another.

It is noted that although each third electrode 32 entirely overlaps the opposing second electrode 24 in plan view in the thickness direction T in FIG. 8, each third electrode 32 may partially overlap the opposing second electrode 24 in plan view in the thickness direction T in an alternative aspect. Moreover, each third electrode 32 may be formed within the area of the corresponding second electrode 24.

The capacitor 3 illustrated in FIGS. 7 and 8 is manufactured, for example, by using the method described in Japanese Patent No. 6372677 noted above.

Hereinafter, each configuration unique to the present embodiment will be described in detail.

The second dielectric film 31 is provided to cover the second electrodes 24 except for an opening. In FIG. 7, the end portions of the second dielectric film 31 are also provided on the surface of the first dielectric film 23 from the end portions of the first electrodes 22 to the first dielectric film 23. The end portions of the second dielectric film 31 need not necessarily be provided to extend to the end portions of the substrate 10.

It is noted that the material of the second dielectric film 31 is not particularly limited, and preferred examples of the material include oxides or nitrides such as SiO₂, SiN, Al₂O₃, HfO₂, and Ta₂O₅.

The third electrodes 32 are provided to face the second electrodes 24 with the second dielectric film 31 interposed therebetween. More specifically, the third electrodes 32 include a third electrode 32A facing the second electrode 24A, a third electrode 32B facing the second electrode 24B, and a third electrode 32C facing the second electrode 24C.

It is noted that the material of the third electrodes 32 is not particularly limited, and preferred examples of the material include Cu, Ag, Au, Al, Ni, Cr, Ti, and an alloy containing at least one of these metals.

The outer electrodes 27 configured as the terminal electrodes 27A and 27B are electrically coupled to the capacitor elements (in this case, the capacitor elements CAP4 and CAP3) coupled in series at both ends among the six capacitor elements CAP1 to CAP6. More specifically, the outer electrodes 27 serving as the terminal electrodes 27A and 27B are coupled to the third electrode 32A and the first electrode 22B, respectively.

The outer electrode 27C not serving as the terminal electrodes 27A and 27B is electrically coupled to two capacitor elements (in this case, the capacitor elements CAP5 and CAP6) among the six capacitor elements CAP1 to CAP6, other than the capacitor elements couple in series at both ends. More specifically, the outer electrode 27C is coupled to the third electrodes 32B and 32C.

The present embodiment provides a capacitor that includes a greater number of capacitor elements coupled in series, in which the capacitance center is adjusted and the capacitance variation is further reduced. In addition, the chip can be downsized.

### Fourth Exemplary Embodiment

A capacitor according to the fourth exemplary embodiment of the present disclosure is different from the capacitor of the third exemplary embodiment in that the former further includes a third dielectric film and three (that is, M=3) fourth electrodes over the three (that is, M=3) third electrodes, and in that the areas of at least two of the three fourth electrodes are different from each other.

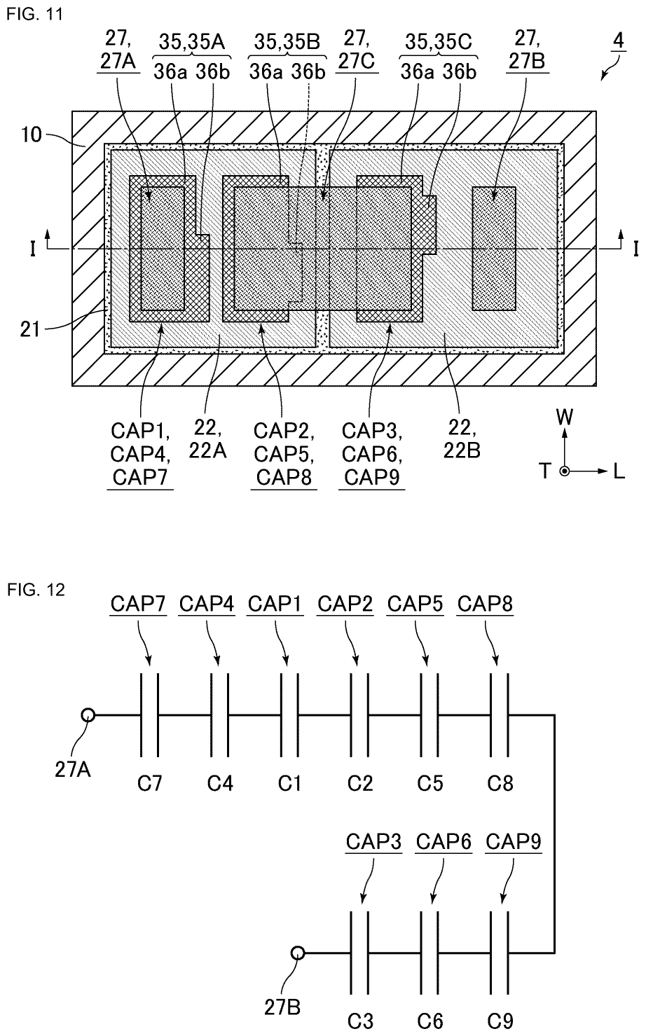

FIG. 10 is a schematic cross-sectional view of an example of a capacitor according to the fourth exemplary embodiment. FIG. 11 is a schematic plan view of the example of the capacitor according to the fourth exemplary embodiment. FIG. 10 is a cross-sectional view of the capacitor illustrated in FIG. 11, taken along line I-I. FIG. 12 illustrates an equivalent circuit of the capacitor illustrated in FIGS. 10 and 11.

The capacitor 4 illustrated in FIGS. 10 and 11 further includes a third dielectric film 34 provided on the three third electrodes 32, and three fourth electrodes 35 each provided over the corresponding one of the three third electrodes 32 with the third dielectric film 34 interposed therebetween.

Specifically, the three third electrodes 32, the third dielectric film 34, and the three fourth electrodes 35 form three capacitor elements CAP7, CAP8, and CAP9, and the nine capacitor elements CAP1 to CAP9 are electrically coupled in series (see FIG. 12).

Thus, the present embodiment has an increased number of capacitor elements coupled in series, thereby further reducing the capacitance variation. In addition, since the capacitor elements are formed in the thickness direction, the chip can be downsized.

In the capacitor 4 illustrated in FIGS. 10 and 11, the areas of at least two of the three fourth electrodes 35 are different from each other. This configuration makes it possible to adjust the capacitance center. This is because the area of each fourth electrode 35 can be set such that the film thickness distribution of the third dielectric film 34 on the wafer surface is canceled.

More specifically, each fourth electrode 35 includes a first region 36a having a rectangular plan-view shape and a second region 36b having a rectangular plan-view shape protruding from the first region 36a. Then, whereas the areas of the first regions 36a of the three fourth electrodes 35 are the same, the areas of the second regions 36b of at least two of the three fourth electrodes 35 are different from each other.

It is noted that the areas of all of the fourth electrodes 35 may be different from one another, and the areas of the second regions 36b of all of the fourth electrodes 35 may be different from one another.

Moreover, it is noted that although each fourth electrode 35 entirely overlaps the opposing third electrode 32 in plan view in the thickness direction T in FIG. 11, each fourth electrode 35 may partially overlap the opposing third electrode 32 in plan view in the thickness direction T in an alternative aspect. In addition, although each third electrode 32 entirely overlaps the opposing second electrode 24 in plan view in the thickness direction T in FIG. 11, each third electrode 32 may partially overlap the opposing second electrode 24 in plan view in the thickness direction T in an alternative aspect. Each fourth electrode 35 may be formed within the area of the corresponding third electrode 32, and each third electrode 32 may be formed within the area of the corresponding second electrode 24.

The capacitor 4 illustrated in FIGS. 10 and 11 is manufactured, for example, by using the method described in Japanese Patent No. 6372677 noted above.

Hereinafter, each configuration unique to the present embodiment will be described in detail.

The third dielectric film 34 is provided to cover the third electrodes 32 except for an opening. In FIG. 10, the end portions of the third dielectric film 34 are also provided on the surface of the second dielectric film 31 from the end portions of the first electrodes 22 to the second dielectric film 31. It is noted that the end portions of the third dielectric film 34 need not necessarily be provided to extend to the end portions of the substrate 10.

It is noted that the material of the third dielectric film 34 is not particularly limited, and preferred examples of the material include oxides or nitrides such as SiO₂, SiN, Al₂O₃, HfO₂, and Ta₂O₅.

The fourth electrodes 35 are provided to face the third electrodes 32 with the third dielectric film 34 interposed therebetween. More specifically, the fourth electrodes 35 include a fourth electrode 35A facing the third electrode 32A, a fourth electrode 35B facing the third electrode 32B, and a fourth electrode 35C facing the third electrode 32C.

It is noted that the material of the fourth electrodes 35 is not particularly limited, and preferred examples of the material include Cu, Ag, Au, Al, Ni, Cr, Ti, and an alloy containing at least one of these metals.

The outer electrodes 27 configured as the terminal electrodes 27A and 27B are electrically coupled to the capacitor elements (in this case, the capacitor elements CAP7 and CAP3) coupled in series at both ends among the nine capacitor elements CAP1 to CAP9. More specifically, the outer electrodes 27 configured as the terminal electrodes 27A and 27B are coupled to the fourth electrode 35A and the first electrode 22B, respectively.

The outer electrode 27C not serving as the terminal electrodes 27A and 27B is electrically coupled to two capacitor elements (in this case, the capacitor elements CAP8 and CAP9) among the nine capacitor elements CAP1 to CAP9, other than the capacitor elements coupled in series at both ends. More specifically, the outer electrode 27C is coupled to the fourth electrodes 35B and 35C.

The present embodiment provides a capacitor that includes a greater number of capacitor elements coupled in series, in which the capacitance center is adjusted and the capacitance variation is even further reduced. In addition, the chip can be downsized.

### Fifth Exemplary Embodiment

A capacitor according to the fifth exemplary embodiment of the present disclosure is different from the capacitor of the second exemplary embodiment in that the former includes element isolation provided in the semiconductor substrate and extending between the three capacitor elements.

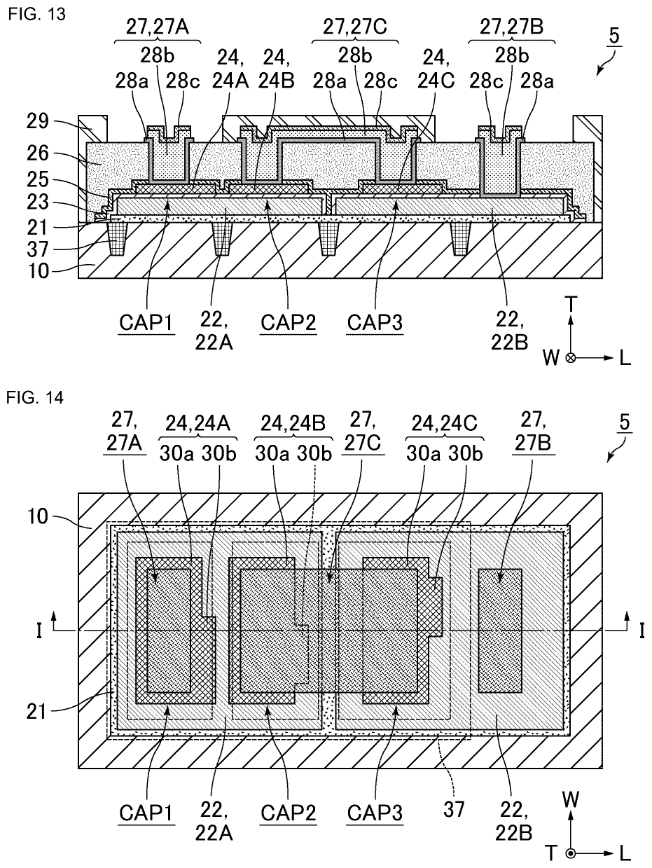

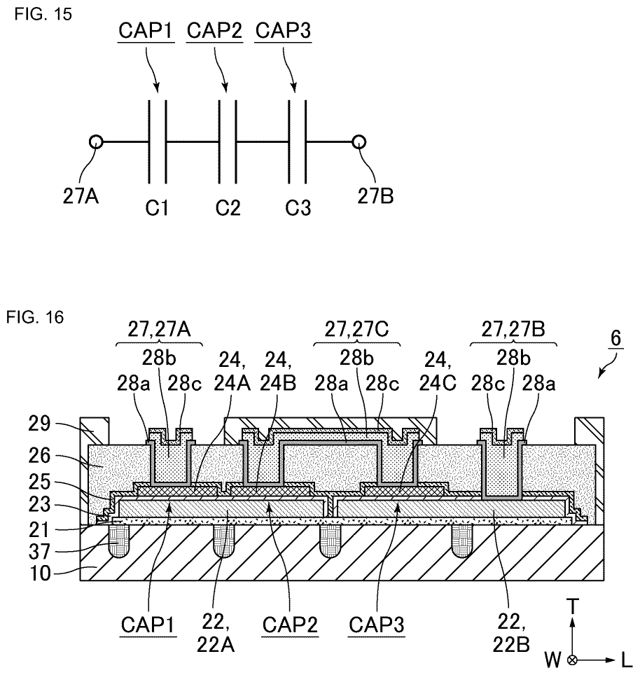

FIG. 13 is a schematic cross-sectional view of an example of a capacitor according to the fifth exemplary embodiment. FIG. 14 is a schematic plan view of the example of the capacitor according to the fifth exemplary embodiment. FIG. 13 is a cross-sectional view of the capacitor illustrated in FIG. 14, taken along line I-I. FIG. 15 illustrates an equivalent circuit of the capacitor illustrated in FIGS. 13 and 14.

In the capacitor 5 illustrated in FIGS. 13 and 14, the substrate 10 is a semiconductor substrate, and element isolation 37 is provided in the semiconductor substrate and extends between the three capacitor elements CAP1, CAP2, and CAP3.

This configuration reduces the electric current flowing in the semiconductor substrate between adjacent capacitor elements, thereby reducing the mutual interference between adjacent capacitor elements. Thus, the accuracy in the capacitance center value and capacitance variation of the capacitor 5 is increased.

Specifically, the element isolation 37 has a structure (STI: shallow trench isolation) in which a cavity is formed in the semiconductor substrate, and an SiO₂ film is embedded.

As illustrated in FIG. 14, the element isolation 37 is provided to extend at least between adjacent capacitor elements (in this case, between the capacitor elements CAP1 and CAP2 and between the capacitor elements CAP2 and CAP3) and preferably to surround each of the capacitor elements CAP1, CAP2, and CAP3. The element isolation 37 preferably overlaps the peripheral edge portions of the first electrodes 22 and extends along the peripheral edge portions.

### Sixth Exemplary Embodiment

A capacitor according to the sixth exemplary embodiment of the present disclosure is different from the capacitor according to the fifth exemplary embodiment in that the material of the element isolation is different from that of the fifth embodiment.

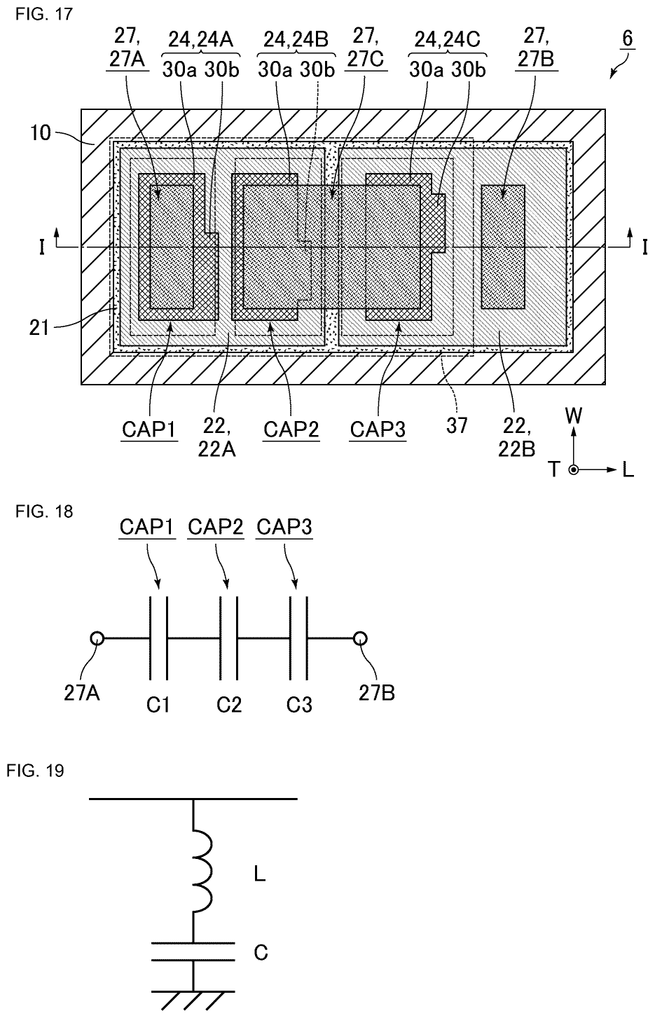

FIG. 16 is a schematic cross-sectional view of an example of a capacitor according to the sixth exemplary embodiment. FIG. 17 is a schematic plan view of the example of the capacitor according to the sixth exemplary embodiment. FIG. 16 is a cross-sectional view of the capacitor illustrated in FIG. 17, taken along line I-I. FIG. 18 illustrates an equivalent circuit of the capacitor illustrated in FIGS. 16 and 17.

In the capacitor 6 illustrated in FIGS. 16 and 17, the substrate 10 is an n-type semiconductor substrate, and the element isolation 37 has a structure in which a p+ active layer is formed in the n-type semiconductor substrate. The element isolation 37 mentioned above can be formed, for example, by heavily implanting p-type impurities into an n-type semiconductor substrate by an ion implantation method.

The present exemplary embodiment also reduces the electric current flowing in the semiconductor substrate between adjacent capacitor elements, thereby reducing the mutual interference between adjacent capacitor elements. Thus, the accuracy in the capacitance center value and capacitance variation of the capacitor 6 can be increased.

### Additional Exemplary Embodiments

It is noted that the semiconductor device of the exemplary aspects of the present disclosure is not limited to the embodiments described above, and the configurations, the manufacturing conditions, and the like of the semiconductor device such as a capacitor may be applied or changed in various ways within the scope of the exemplary aspects of the present disclosure.

For example, although the description of the above embodiments is based on examples in which M=3, M is not particularly limited as long as it is an integer of 3 or more that satisfies M>N. For example, M may be 4. For example, the first embodiment may include a fourth second electrode provided over the first electrode 22B with the first dielectric film 23 interposed therebetween, and the fourth second electrode may be coupled to the terminal electrode 27B. In the third embodiment, a fourth second electrode may be provided over the first electrode 22B with the first dielectric film 23 interposed therebetween, a fourth third electrode may be provided over the fourth second electrode with the second dielectric film 31 interposed therebetween, and the fourth third electrode may be coupled to the terminal electrode 27B. In addition, in the fourth embodiment, a fourth second electrode may be provided over the first electrode 22B with the first dielectric film 23 interposed therebetween, a fourth third electrode may be provided over the fourth second electrode with the second dielectric film 31 interposed therebetween, a fourth fourth electrode may be provided over the fourth third electrode with the third dielectric film 34 interposed therebetween, and the fourth fourth electrode may be coupled to the terminal electrode 27B.

Moreover, it is noted that although the description of the above exemplary embodiments is based on cases in which N=2, N is not particularly limited as long as N is an integer of 2 or more. For example, N may be 3. For example, in the first embodiment, the following configuration is possible. A third first electrode is provided between the two first electrodes 22A and 22B, and fourth and fifth second electrodes are provided over the third first electrode with the first dielectric film 23 interposed therebetween, thereby forming fourth and fifth capacitor elements (a total of five capacitor elements coupled in series). Then, the fourth capacitor element and the capacitor element CAP2 are electrically coupled in series by an outer electrode not serving as the terminal electrodes 27A and 27B, and the fifth capacitor element and the capacitor element CAP3 are electrically coupled in series by an outer electrode not serving as the terminal electrodes 27A and 27B.

### REFERENCE SIGNS LIST

1, 2, 3, 4, 5, 6 capacitor (semiconductor device)
10 substrate
21 insulating film
22, 22A, 22B first electrode
23 first dielectric film
24, 24A, 24B, 24C second electrode
25 moisture resistance film
26 first protective layer
27 outer electrode
27A, 27B outer electrode (terminal electrode)
27C outer electrode (connection wiring line)
28a seed layer
28b first plating layer
28c second plating layer
29 second protective layer
30a second electrode first region
30b second electrode second region
31 second dielectric film
32, 32A, 32B, 32C third electrode
33a third electrode first region
33b third electrode second region
34 third dielectric film
35, 35A, 35B, 35C fourth electrode
36a fourth electrode first region
36b fourth electrode second region
37 element isolation
CAP1 to CAP9 capacitor element

1. A semiconductor device comprising:
a substrate;
N first electrodes over the substrate, where N is an integer of 2 or more;
a first dielectric film on the N first electrodes;
M second electrodes over the N first electrodes with the first dielectric film interposed between the N first electrodes and M second electrodes, where M is an integer of 3 or more and M>N;
a first protective layer that covers the N first electrodes and the M second electrodes;
three or more outer electrodes that extend through the first protective layer; and
a second protective layer that covers each outer electrode of the three or more outer electrodes, other than two outer electrodes,
wherein at least one of the M second electrodes is located over each first electrode, respectively,
wherein the N first electrodes, the first dielectric film, and the M second electrodes form M capacitor elements that are electrically coupled in series,
wherein each pair of capacitor elements of the M capacitor elements, including two of the M second electrodes located over the respective first electrode, are electrically coupled in series by the same first electrode,
wherein the two outer electrodes not covered by the second protective layer are configured as terminal electrodes that are respectively electrically coupled to two capacitor elements of the M capacitor elements,
wherein each pair of capacitor elements of the M capacitor elements, including two of the second electrodes located over different first electrodes of the N first electrodes, are electrically coupled in series by a respective outer electrode that is not configured as one of the terminal electrodes.

2. The semiconductor device according to claim 1, wherein each outer electrode that is not configured as one of the terminal electrodes is covered with the second protective layer.

3. The semiconductor device according to claim 1, wherein areas of at least two second electrodes of the M second electrodes are different from each other.

4. The semiconductor device according to claim 1, further comprising a second dielectric film on the M second electrodes.

5. The semiconductor device according to claim 4, wherein M third electrodes are each disposed over a corresponding second electrode of the M second electrodes with the second dielectric film interposed therebetween.

6. The semiconductor device according to claim 5, wherein areas of at least two third electrodes of the M third electrodes are different from each other.

7. The semiconductor device according to claim 5, further comprising a third dielectric film on the M third electrodes.

8. The semiconductor device according to claim 7, wherein M fourth electrodes are each disposed over a corresponding third electrode of the M third electrodes with the third dielectric film interposed therebetween.

9. The semiconductor device according to claim 8, wherein areas of at least two fourth electrodes of the M fourth electrodes are different from each other.

10. The semiconductor device according to claim 1, wherein the substrate is a semiconductor substrate that includes an element isolation that extends between the M capacitor elements.

11. The semiconductor device according to claim 1, wherein at least a portion of the N first electrodes are disposed at positions away from end portions of the substrate.

12. The semiconductor device according to claim 1, wherein areas in a plan view of at least two second electrodes of the M second electrodes are a same area as each other.

13. The semiconductor device according to claim 1, wherein each outer electrode comprises a multilayer structure including a seed layer, a first plating layer and a second plating layer.

14. The semiconductor device according to claim 10, wherein the element isolation surrounds the M capacitor elements.

15. The semiconductor device according to claim 14, wherein the element isolation overlaps peripheral edge portions of the N first electrodes.

16. A semiconductor device comprising:
a substrate;
at least two first electrodes over the substrate;
a first dielectric film on the at least two first electrodes first electrodes;
at least three second electrodes over the at least two first electrodes, such that the first dielectric film is interposed therebetween;
a first protective layer that covers the at least two first electrodes and the at least three second electrodes;
three or more outer electrodes that extend through the first protective layer, the three or more outer electrodes including two terminal electrodes; and
a second protective layer that covers each of the three or more outer electrodes except the two terminal electrodes,
wherein each of the at least three second electrodes is located over a first electrode of the at least two first electrodes,
wherein the at least two first electrodes, the first dielectric film, and the at least three second electrodes form a plurality of capacitor elements that are electrically coupled in series,
wherein a pair of capacitor elements of the plurality of capacitor elements, including two electrodes of the at least three second electrodes located over a same first electrode of the at least two first electrodes, are electrically coupled in series by the same first electrode.

17. The semiconductor device according to claim 16, wherein:
the two terminal electrodes are electrically coupled to two capacitor elements of the plurality of capacitor elements, respectively,
a pair of capacitor elements of the plurality of capacitor elements, including two electrodes of the at least three second electrodes located over different first electrodes of the at least two first electrodes, are electrically coupled in series by a respective outer electrode other than one of the terminal electrodes.

18. The semiconductor device according to claim 17, wherein each outer electrode other than the two terminal electrodes is covered with the second protective layer.

19. The semiconductor device according to claim 16, wherein areas of at least two second electrodes of the at least three second electrodes are different from each other.

20. The semiconductor device according to claim 16, further comprising:
a second dielectric film on the M second electrodes; and
a plurality of third electrodes that are disposed over a corresponding second electrode of the at least three second electrodes with the second dielectric film interposed therebetween.
